(19) United States
(12) Patent Application Publication
(10) Pub. No.: US 2026/0202365 A1
(43) Pub. Date: Jul. 16, 2026

(54) METHOD TO DETERMINE THE WATER SATURATION USING THE T1/T2 RATIO FOR CONVENTIONAL AND UNCONVENTIONAL FORMATIONS

(71) Applicant: Schlumberger Technology Corporation, Sugar Land, TX (US)

(72) Inventors: Farhan Ali, Dhahran (SA); Chiara Cavalleri, Dhahran (SA); Mohammed AL-HAMAD, Dhahran (SA)

(21) Appl. No.: 19/443,942

(22) Filed: Jan. 8, 2026

Related U.S. Application Data
(60) Provisional application No. 63/743,807, filed on Jan. 10, 2025.

(51) Int. Cl. G01N 24/08; G01N 1/04; G01N 1/44; G01R 33/50

(52) U.S. Cl. CPC G01N 24/081; G01N 1/04; G01N 1/44; G01R 33/50

(57) ABSTRACT

Aspects of the disclosure relate to workflows and analytical methods for characterizing conventional and unconventional geological formation water saturation values through advanced laboratory measurements and correlation techniques of nuclear magnetic resonance value ratios.

### CROSS-REFERENCE TO RELATED APPLICATIONS

The present application claims priority to U.S. Provisional Application 63/743,807 dated Jan. 10, 2025, the entirety of which is incorporated by reference.

### FIELD OF THE DISCLOSURE

Aspects of the disclosure relate to determination of water saturation values in geological stratum. More specifically, aspects of the disclosure relate to determination of water saturation using T₁/T₂ ratio for conventional and unconventional formations.

### BACKGROUND

Determination of water saturation levels in hydrocarbon recovery projects is a fundamental aspect of reservoir evaluation and production optimization. Water saturation refers to the proportion of pore space within a rock formation that is occupied by water, as opposed to hydrocarbons. Accurate assessment of water saturation is crucial for estimating recoverable reserves, designing extraction strategies, and predicting future production performance. The primary purpose of water saturation determination is to distinguish between productive hydrocarbon zones and water-bearing formations, thereby guiding efficient resource management and reducing unnecessary operational costs.

Despite its importance, the process of determining water saturation presents several technological challenges. Many conventional methods rely on indirect measurements, such as resistivity logging and nuclear magnetic resonance (NMR), which can be influenced by factors like formation heterogeneity, clay content, and fluid distribution. These limitations often result in uncertainties and inconsistencies in the calculated water saturation values, particularly in complex or unconventional reservoirs. The lack of direct measurement techniques and the dependence on laboratory experiments further complicate the process, making it difficult to achieve consistently reliable results.

The technology used for water saturation determination is often difficult to operate, requiring specialized equipment and extensive training. Procedures such as NMR measurements and core analysis involve sophisticated instruments and intricate protocols that must be precisely followed to ensure accurate data collection. Field personnel are required to possess significant technical expertise, and even minor deviations from established procedures can lead to erroneous results. This operational complexity can hinder widespread adoption and limit the effectiveness of water saturation assessment in many hydrocarbon recovery projects.

Economic restrictions also play a significant role in limiting the use of advanced water saturation determination technologies. The cost of acquiring high-resolution data through laboratory experiments, specialized logging tools, and core sampling can be prohibitive, especially for smaller operators and in marginal fields. These economic barriers may force companies to rely on less accurate, cost-effective methods, which can negatively impact reservoir management and overall project profitability. Additionally, the need for repeated measurements and ongoing maintenance of equipment adds to the financial burden.

In nuclear magnetic resonance, T₁ and T₂ are fundamental relaxation times that describe how nuclear spins return to equilibrium after being disturbed by a magnetic field. T₁, known as the longitudinal or spin-lattice relaxation time, measures the time required for the spins to realign with the main magnetic field, representing energy exchange between the spins and their surrounding environment. T₂, the transverse or spin-spin relaxation time, characterizes how quickly the spins lose phase coherence with each other in the plane perpendicular to the magnetic field, due to interactions among neighboring spins. These values are critical for interpreting NMR data, as they provide insight into molecular dynamics, pore structure, and fluid distribution within geological formations.

Specifically, T₂ cutoff is an indication of which part of the T₂ spectra is resistant from being removed when the sample is desaturated. This is; therefore, connected to the pore size, pore throat, and wettability combined. NMR in principle is not sensitive to pore throat, but it is sensitive to pore size and wettability. The presence of a correlation between pore size and pore throat in most of the rocks allow determination of permeability from NMR. Typically, only one dimensional NMR T₂ measurements are performed for the T₂ cutoff in addition to centrifuge desaturation on core samples. A graphical representation of T₂ cutoff is shown in FIG. 1.

Two dimensional T₁T₂ data has been used for qualitative wettability assessment. Using T₁-T₂ data (rather than D-T₂, on which all the restricted diffusion is based) considerably increases the applicability of the technique. Good quality diffusion data sets are only achievable for relatively long T₂ (typically above 10 ms). This limit makes D-T₂ difficult to apply (or even impossible) on tight rocks and in general for unconventional resources.

While T₂ cutoff is a critical parameter required in the processing of NMR data, especially logs where it is near impossible to determine the proper saturation of the rock, T₂ cutoff determination is not straightforward and often requires experience on the specific reservoir. The standard methodology of obtaining a T₂ cutoff is based on lab experiments, wherein this process is expensive and time consuming, as it requires expensive coring and lab experimentation.

There is a need for resolving the problems described above. Addressing technological limitations and improving the reliability of water saturation determination techniques would allow for more accurate reservoir characterization and better decision making in hydrocarbon recovery operations.

There is an additional need for providing a technology that solves the economic restrictions described above. Developing cost-effective solutions would enable broader access to precise water saturation data, benefiting both large and small operators, and supporting more sustainable resource development.

There is an additional need for providing a technology that is easy to operate and that does not require specialized training. Simplifying the operation of water saturation determination tools would make the technology more accessible to field personnel, reduce the risk of error, and promote more consistent application across diverse hydrocarbon recovery environments.

### SUMMARY

So that the manner in which the above recited features of the present disclosure can be understood in detail, a more particular description of the disclosure, briefly summarized below, may be had by reference to embodiments, some of which are illustrated in the drawings. It is to be noted that the drawings illustrate only typical embodiments of this disclosure and are; therefore, not to be considered limiting of its scope, for the disclosure may admit to other equally effective embodiments without specific recitation. Accordingly, the following summary provides just a few aspects of the description and should not be used to limit the described embodiments to a single concept.

In one non-limiting embodiment, a method for determining a water saturation value of a geological formation is disclosed. The method may comprise obtaining at least one sample of the geological formation. The method may further comprise subjecting the at least one sample to a first nuclear magnetic resonance evaluation, wherein cutoff values are obtained when the at least one sample is saturated. The method may further comprise desaturating the at least one sample. The method may further comprise performing a second nuclear magnetic resonance evaluation of the desaturated at least one sample. The method may further comprise comparing the first nuclear magnetic resonance evaluation to the second nuclear magnetic resonance evaluation. The method may further comprise generating at least one correlation between the first and second nuclear magnetic resonance evaluations. The method may further comprise determining the water saturation value of the geological formation based on the at least one correlation.

In another example embodiment, a method for determining a water saturation value of a shale geological formation is disclosed. The method may comprise obtaining at least one sample of the geological formation. The method may further comprise subjecting the at least one sample to a first nuclear magnetic resonance evaluation, wherein cutoff values are obtained when the at least one sample is in a native state. The method may further comprise obtaining a porosity and a permeability of the at least one sample. The method may further comprise selecting a first of the at least one sample based upon the obtained porosity and permeability. The method may further comprise spinning the first sample in air to remove fluid from the sample. The method may further comprise performing a second nuclear magnetic resonance evaluation of the spun first sample. The method may further comprise saturating the first sample. The method may further comprise obtaining a saturation porosity of the first sample. The method may further comprise conducting a third nuclear magnetic resonance evaluation. The method may further comprise spinning the first sample at least one time. The method may further comprise conducting a nuclear magnetic resonance evaluation after each spinning of the first sample. The method may further comprise performing cutoff measurements of the first sample. The method may further comprise comparing the nuclear magnetic resonance evaluations in the saturated state and the spun state. The method may further comprise generating at least one correlation based on the comparing. The method may further comprise determining the water saturation value of the geological formation based on the at least one correlation.

In another example embodiment, an article of manufacture is disclosed. The article of manufacture is configured to provide instructions that will be performed on a computing device, wherein the article of manufacture has a non-transitory memory configured to retain the instructions, the instructions comprising, at least in part: obtaining at least one sample of the geological formation. The instructions may further comprise subjecting the at least one sample to a first nuclear magnetic resonance evaluation, wherein cutoff values are obtained when the at least one sample is saturated. The instructions may further comprise desaturating the at least one sample. The instructions may further comprise performing a second nuclear magnetic resonance evaluation of the desaturated at least one sample. The instructions may further comprise comparing the first nuclear magnetic resonance evaluation to the second nuclear magnetic resonance evaluation. The instructions may further comprise generating at least one correlation between the first and second nuclear magnetic resonance evaluations. The instructions may further comprise determining the water saturation value of the geological formation based on the at least one correlation.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the drawings. It is to be noted; however, that the appended drawings illustrate only typical embodiments of this disclosure and are therefore not be considered limiting of its scope, for the disclosure may admit to other equally effective embodiments.

FIG. 1 is a graphical representation of T₂ cutoff, according to one or more examples of the disclosure.

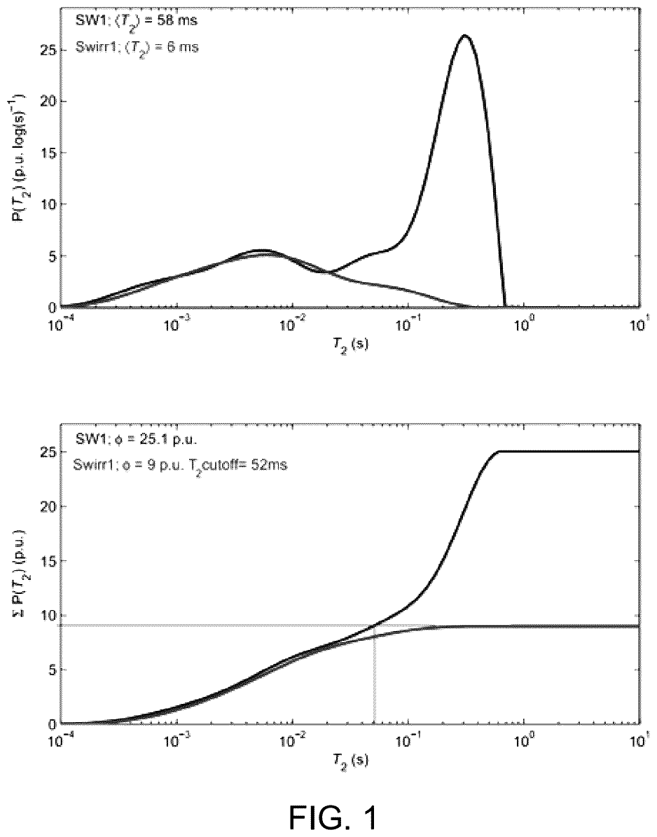

FIG. 2 is a flowchart depicting a workflow of the present method for conventional formations, according to one or more examples of the disclosure.

FIG. 3 is a flowchart depicting a workflow of the present method for unconventional formations, according to one or more examples of the disclosure.

To facilitate understanding, identical reference numerals have been used, where possible, to designate identical elements that are common to the figures (“FIGS”). It is contemplated that elements disclosed in one embodiment may be beneficially utilized on other embodiments without specific recitation.

### DETAILED DESCRIPTION

In the following, reference is made to embodiments of the disclosure. It should be understood; however, that the disclosure is not limited to specific described embodiments. Instead, any combination of the following features and elements, whether related to different embodiments or not, is contemplated to implement and practice the disclosure. Furthermore, although embodiments of the disclosure may achieve advantages over other possible solutions and/or over the prior art, whether or not a particular advantage is achieved by a given embodiment is not limiting of the disclosure. Thus, the following aspects, features, embodiments, and advantages are merely illustrative and are not considered elements or limitations of the claims except where explicitly recited in a claim. Likewise, reference to “the disclosure” shall not be construed as a generalization of inventive subject matter disclosed herein and should not be considered to be an element or limitation of the claims except where explicitly recited in a claim.

Although the terms first, second, third, etc., may be used herein to describe various elements, components, regions, layers, and/or sections, these elements, components, regions, layers, and/or sections should not be limited by these terms. These terms may be only used to distinguish one element, components, region, layer, or section from another region, layer, or section. Terms such as “first”, “second”, and other numerical terms, when used herein, do not imply a sequence or order unless clearly indicated by the context. Thus, a first element, component, region, layer, or section discussed herein could be termed a second element, component, region, layer, or section without departing from the teachings of the example embodiments.

When an element or layer is referred to as being “on”, “engaged to”, “connected to”, or “coupled to” another element or layer, it may be directly on, engaged, connected, or coupled to the other element or layer, or interleaving elements or layers may be present. In contrast, when an element is referred to as being “directly on”, “directly engaged to”, “directly connected to”, or “directly coupled to” another element or layer, there may be no interleaving elements or layers present. Other words used to describe the relationship between elements should be interpreted in a like fashion. As used herein, the term “and/or” includes any and all combinations of one or more of the associated listed terms.

Some embodiments will now be described with reference to the figures. Like elements in the various figures will be referenced with like numbers for consistency. In the following description, numerous details are set forth to provide an understanding of various embodiments and/or features. It will be understood; however, by those skilled in the art, that some embodiments may be practiced without many of these details, and that numerous variations or modifications from the described embodiments are possible. As used herein, the terms “above” and “below”, “up” and “down”, “upper” and “lower”, “upwardly” and “downwardly”, and other like terms indicating relative positions above or below a given point are used in this description to more clearly describe certain embodiments.

Embodiments of the disclosure may provide for an article of manufacture that contains a non-transitory memory product. The non-transitory memory product may be configured to retain data, such as method steps. The non-transitory memory product may be stored data and may be read by a device. Such devices may be computing devices such as a laptop computer, main frame computer, computer cell phone or other similar device. The method steps may be used, for example, to control a computer or perform mathematical calculations. In turn, the computer may instruct other systems, machines or components. Example non-transitory memory products may include universal serial bus devices, solid state memory arrangements, compact discs or computer hard drives. In some instances, the non-transitory device may be configured with a device that reads the stored information and transmits the data to a separate location. In some embodiments, artificial intelligence may be used in conjunction with the data stored on the article of manufacture to perform various functions.

Further embodiments may include methodologies that allow computers to be trained to allow for more comprehensive and accurate answers. Such training may be performed in nodes that may be used to allow for fine tuning of results. Upon retention of results of calculations, the method steps may be altered such that results that are not accurate are precluded from future calculations by amending method steps accomplished in various nodes. Such alterations are contemplated and are within the scope of this disclosure.

Aspects of the disclosure relate to determination of water saturation for conventional and unconventional formations. Determining T₂ cutoff values for conventional formations and unconventional formations may include using multiple points of data related to formation data. These cutoff values are then used to generate generalized correlations for the formation. The generated correlations can accurately estimate actual cutoff without any measurements on core samples. Robust correlations for water saturation can also be determined. In aspects of the disclosure, the conventional formations may be carbonates or sandstones, while the unconventional formations may be shales. The generated correlations may work on lab data as well as downhole data for wireline and/or logging while drilling (LWD) applications. Accurate permeability estimation may be obtained using the generated correlations. Aspects of the present disclosure also include a system for determining T₂ cutoff for conventional formations and unconventional formations, including a processor, a memory accessible to the processor, processor executable instructions stored in the memory and executable by the processor to instruct the system to use multiple points to determine cutoff values, and use the cutoff values to generate correlations. The generated correlations developed can accurately estimate actual cutoff without any measurements on core samples. Robust correlations for water saturation can also be determined.

Aspects described herein relate to a workflow which provides correlations to calculate accurate T₂ cutoffs and assist with saturation calculations using the developed correlations with 2D NMR T₁-T₂ measurements. These correlations are obtained using multiple core samples at multiple desaturation steps. The results were averaged for corresponding formations. These correlations can be used downhole. The advantages of having a downhole alternative to determine the T₂ cutoff in the lab are as follows:
a. Can be available right after logging (or even during, i.e. LWD)
b. Does not require coring
c. Does not require time consuming lab work.

### Workflow for Conventional Formation

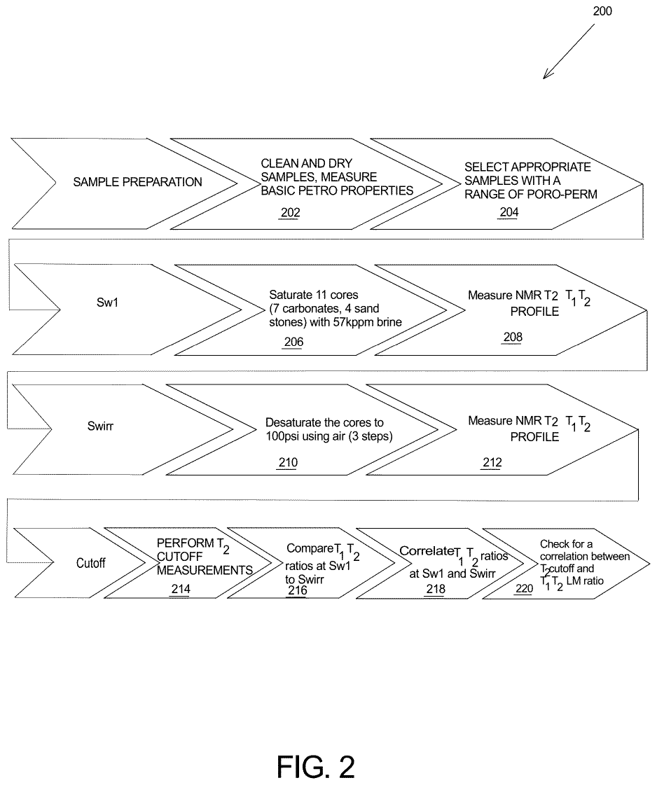

In one example embodiment, a T₁-T₂ correlation is performed on core samples (from which information is extracted on a T₁/T₂ ratio) at a fully water saturated condition (SW1). The values T₁ and T₂ are determined/measured simultaneously. The core samples are then centrifuged with air at different speeds to attain lower water saturation i.e. Sw=SW_{irr, air}, with NMR being measured at each water saturation state. Using these data sets, a correlation between the T₁/T₂ ratio of the remaining water fraction is examined, which provides a possible way to separate the bound and free fluid fractions, i.e. cutoff, based on the T₁/T₂ ratio. To avoid the influence of wettability, cleaned, water-wet outcrops samples were used. The core samples were saturated with 57,000 parts per million (ppm) equivalent NaCl brine. This is graphically presented below in FIG. 2.

Referring to FIG. 2, a method 200 in one example embodiment of the disclosure is illustrated. The method may comprise, at 202, cleaning and drying samples to be analyzed. The method may further comprise, at 204, of selecting samples within a range desired for porosity and permeability. The method may further comprise determining basic petrophysical properties. The method may further comprise, at 206, suturing cores with a brine. In one non-limiting embodiment, the brine is a 57,000 ppm brine. In another example embodiment, 11 cores may be used in which 7 are carbonate cores, and 4 are sand stone cores. At 208, NMR may be used to measure T₂, T₁T₂ profiles.

Further referring to FIG. 2, the method may continue with, at 210, desaturating the cores to 100 psi using air. In one example embodiment, this desaturation may occur over 3 steps. The method may continue, at 212, with measuring NMR profiles T₂, T₁T₂. At 214, the method may continue with performing T₂ cutoff measurements. At 216, T₁ T₂ ratios previously at steps 206 and 208 to 210 and 212 are compared. At 218, T₁ T₂ ratios 208 and 210 to 214 and 216 are correlated. At 220, the method concludes with checking for a correlation between T₂ cutoff and T₁ T₂ LM ratio.

### Workflow for Unconventional Formation

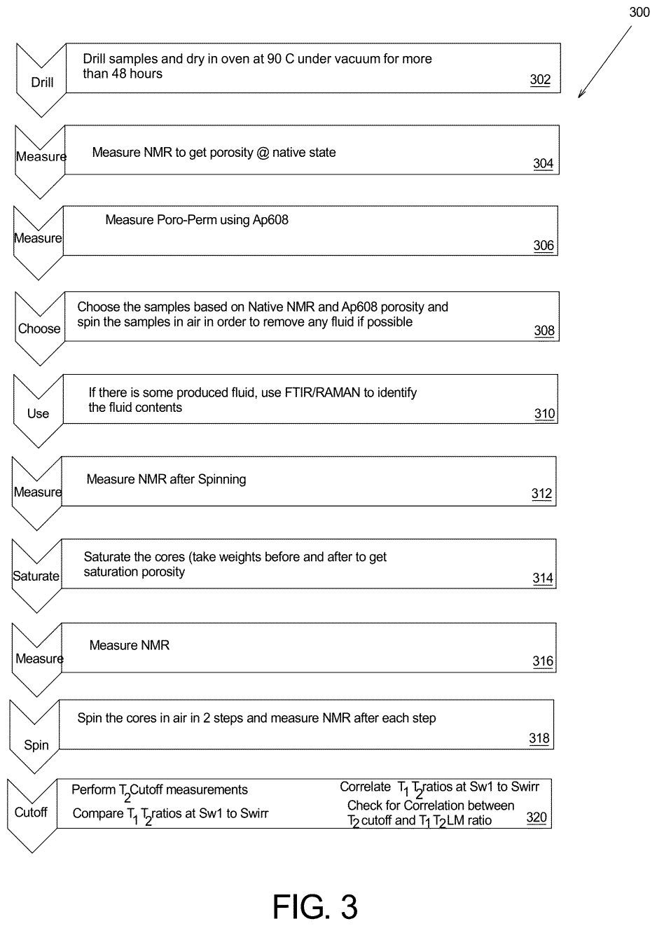

A method for unconventional formations is illustrated in FIG. 3. In this particular embodiment, method relates to shales and is different compared to the method of the carbonates and the sandstones in FIG. 2. In this embodiment, outcrop samples were plugged from a block and subsequently dried to remove humidity. Poro-Perm and NMR measurements on dry cores were first performed, before which the samples were fully saturated with 57,000 ppm equivalent NaCl brine. The samples were then centrifuged with air, with the applied capillary pressures being much higher compared to the carbonate and sandstone samples.

The correlations obtained for both conventional and unconventional formations based on different parameters are listed in Table 1 below.

Correlations of Different Parameters between Conventional and Unconventional Formations

TABLE 1

| | | T₂ Cutoff vs Sw | T₁/T₂lm vs Sw | T₂ Cutoff vs T₁/T₂lm |
|---|---|---|---|---|
| Carbonates | Correlation | T₂ Cutoff = 1493*Sw − 375.72 | T₁/T₂lm = −0.657*Sw + 2.3917 | T₂ Cutoff = −1264.4*T₁/T₂lm + 2957 |
| | R₂ | 0.966 | 0.773 | 0.928 |
| Sandstones | Correlation | T₂ Cutoff = 764.97*Sw − 297.39 | T₁/T₂lm = −0.7669*Sw + 2.3963 | T₂ Cutoff = −848.08*T₁/T₂lm + 1804.6 |
| | R₂ | 0.955 | 0.951 | 0.797 |
| Shales | Correlation | T₂ Cutoff = 110.94*Sw − 99.641 | T₁/T₂lm = −8.3945*Sw + 17.055 | T₂ Cutoff = −11.194*T₁/T₂lm + 107.02 |
| | R₂ | 0.896 | 0.945 | 0.997 |

Referring to FIG. 3, a second method 300 according to one non-limiting embodiment of the disclosure is shown. The method may comprise, at 302, drilling and obtaining samples. The samples obtained may be dried in an oven at 90 degrees Celsius under vacuum for more than 48 hours. At 304, using NMR, the porosity of obtained for at least one sample at its native state. At 306, porosity and permeability are measured. At 308, based on the samples' NMR porosity at 304 and 306, spin the samples in air in order to remove fluids. At 310, for any fluid produced, at 308, identification is performed. At 312, perform a second measurement of NMR. At 314, saturate the cores (taking weights before and after) to obtain a saturation porosity. At 316, measure the cores with NMR. At 318, spin the cores in air in 2 steps and measure NMR after each step. At 320, the method continues with performing T₂ cutoff measurements, comparing T₁ T₂ ratios correlating T₁ T₂ and checking for a correlation between T₂ cutoff and T₁ T₂ LM ratio.

Example embodiments of the claims are recited next. The recitation of these claims should not be considered limiting. In one non-limiting embodiment, a method for determining a water saturation value of a geological formation is disclosed. The method may comprise obtaining at least one sample of the geological formation. The method may further comprise subjecting the at least one sample to a first nuclear magnetic resonance evaluation, wherein cutoff values are obtained when the at least one sample is saturated. The method may further comprise desaturating the at least one sample. The method may further comprise performing a second nuclear magnetic resonance evaluation of the desaturated at least one sample. The method may further comprise comparing the first nuclear magnetic resonance evaluation to the second nuclear magnetic resonance evaluation. The method may further comprise generating at least one correlation between the first and second nuclear magnetic resonance evaluations. The method may further comprise determining the water saturation value of the geological formation based on the at least one correlation.

In another example embodiment, the method may further comprise obtaining a porosity and a permeability of the at least one sample after the obtaining of the at least one sample.

In another example embodiment, the method may be performed wherein the at least one sample is selected for nuclear magnetic resonance evaluation based upon at least one of the porosity and the permeability.

In another example embodiment, the method may be performed wherein cutoff measurements are performed after the second nuclear magnetic resonance evaluation.

In another example embodiment, the method may be performed wherein the cutoff measurement ratios are compared in the saturated and desaturated samples.

In another example embodiment, the method may be performed wherein the desaturation is performed in air.

In another example embodiment, the method may be performed wherein the desaturation is performed in three steps.

In another example embodiment, the method may further comprise saturating the at least one sample prior to performing the first nuclear magnetic resonance evaluation.

In another example embodiment, the method may be performed wherein the saturating of the at least one sample is performed in a brine solution.

In another example embodiment, the method may be performed wherein the brine is an approximate 57,000 ppm brine solution.

In another example embodiment, a method for determining a water saturation value of a shale geological formation is disclosed. The method may comprise obtaining at least one sample of the geological formation. The method may further comprise subjecting the at least one sample to a first nuclear magnetic resonance evaluation, wherein cutoff values are obtained when the at least one sample is in a native state. The method may further comprise obtaining a porosity and a permeability of the at least one sample. The method may further comprise selecting a first of the at least one sample based upon the obtained porosity and permeability. The method may further comprise spinning the first sample in air to remove fluid from the sample. The method may further comprise performing a second nuclear magnetic resonance evaluation of the spun first sample. The method may further comprise saturating the first sample. The method may further comprise obtaining a saturation porosity of the first sample. The method may further comprise conducting a third nuclear magnetic resonance evaluation. The method may further comprise spinning the first sample at least one time. The method may further comprise conducting a nuclear magnetic resonance evaluation after each spinning of the first sample. The method may further comprise performing cutoff measurements of the first sample. The method may further comprise comparing the nuclear magnetic resonance evaluations in the saturated state and the spun state. The method may further comprise generating at least one correlation based on the comparing. The method may further comprise determining the water saturation value of the geological formation based on the at least one correlation.

In another example embodiment, the method may be performed wherein the spinning of the first sample occurs in two steps.

In another example embodiment, the method may be performed wherein the obtaining the sample occurs by drilling.

In another example embodiment, the method may be performed wherein the sample is dried in an oven.

In another example embodiment, the method may be performed wherein the sample is dried under a vacuum.

In another example embodiment, the method may be performed wherein a drying time is more than 48 hours.

In another example embodiment, the method may be performed wherein the drying is performed at approximately 90 degrees Celsius.

In another example embodiment, the method may be performed wherein the sample is a shale sample.

In another example embodiment, an article of manufacture is disclosed. The article of manufacture is configured to provide instructions that will be performed on a computing device, wherein the article of manufacture has a non-transitory memory configured to retain the instructions, the instructions comprising, at least in part: obtaining at least one sample of the geological formation. The instructions may further comprise subjecting the at least one sample to a first nuclear magnetic resonance evaluation, wherein cutoff values are obtained when the at least one sample is saturated. The instructions may further comprise desaturating the at least one sample. The instructions may further comprise performing a second nuclear magnetic resonance evaluation of the desaturated at least one sample. The instructions may further comprise comparing the first nuclear magnetic resonance evaluation to the second nuclear magnetic resonance evaluation. The instructions may further comprise generating at least one correlation between the first and second nuclear magnetic resonance evaluations. The instructions may further comprise determining the water saturation value of the geological formation based on the at least one correlation.

In another example embodiment, the article of manufacture may be configured wherein the article is of a form of a solid-state memory device, a compact disk, a computer hard drive, and a universal serial bus device.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may be varied in many ways. Such variations are not to be regarded as a departure from the disclosure, and all such modifications are intended to be included within the scope of the disclosure.

While embodiments have been described herein, those skilled in the art, having benefit of this disclosure, will appreciate that other embodiments are envisioned that do not depart from the inventive scope. Accordingly, the scope of the present claims or any subsequent claims shall not be unduly limited by the description of the embodiments described herein.

What is claimed is:

1. A method for determining a water saturation value of a geological formation, comprising:
obtaining at least one sample of the geological formation;
subjecting the at least one sample to a first nuclear magnetic resonance evaluation, wherein cutoff values are obtained when the at least one sample is saturated;
desaturating the at least one sample;
performing a second nuclear magnetic resonance evaluation of the desaturated at least one sample;
comparing the first nuclear magnetic resonance evaluation to the second nuclear magnetic resonance evaluation;
generating at least one correlation between the first and second nuclear magnetic resonance evaluations; and
determining the water saturation value of the geological formation based on the at least one correlation.

2. The method according to claim 1, further comprising:
obtaining a porosity and a permeability of the at least one sample after the obtaining of the at least one sample.

3. The method according to claim 2, wherein the at least one sample is selected for nuclear magnetic resonance evaluation based upon at least one of the porosity and the permeability.

4. The method according to claim 1, wherein cutoff values are performed after the second nuclear magnetic resonance evaluation.

5. The method according to 4, wherein the cutoff values are compared in the saturated and desaturated samples.

6. The method according to claim 4, wherein the desaturation is performed in air.

7. The method according to claim 6, wherein the desaturation is performed in three steps.

8. The method according to claim 1, further comprising:
saturating the at least one sample prior to performing the first nuclear magnetic resonance evaluation.

9. The method according to claim 8, wherein the saturating of the at least one sample is performed in a brine solution.

10. The method according to claim 9, wherein the brine is an approximate 57,000 parts per million brine solution.

11. A method for determining a water saturation value of a geological formation, comprising:
obtaining at least one sample of the geological formation;
subjecting the at least one sample to a first nuclear magnetic resonance evaluation, wherein cutoff values are obtained when the at least one sample is in a native state;
obtaining a porosity and a permeability of the at least one sample;
selecting a first of the at least one sample based upon the obtained porosity and permeability;
spinning the first sample in air to remove fluid from the sample;
performing a second nuclear magnetic resonance evaluation of the spun first sample;
saturating the first sample;
obtaining a saturation porosity of the first sample;
conducting a third nuclear magnetic resonance evaluation;
spinning the first sample at least one time;
conducting a nuclear magnetic resonance evaluation after each spinning of the first sample;
performing cutoff measurements of the first sample;
comparing the nuclear magnetic resonance evaluations in the saturated state and the spun state;
generating at least one correlation based on the comparing; and
determining the water saturation value of the geological formation based on the at least one correlation.

12. The method according to claim 11, wherein the spinning of the first sample occurs in two steps.

13. The method according to claim 11, wherein the obtaining the sample occurs by drilling.

14. The method according to claim 13, wherein the sample is dried in an oven.

15. The method according to claim 14, wherein the sample is dried under a vacuum.

16. The method according to claim 15, wherein a drying time is more than 48 hours.

17. The method according to claim 16, wherein the drying is performed at approximately 90 degrees Celsius.

18. The method according to claim 13, wherein the sample is a shale sample.

19. An article of manufacture configured to provide instructions that will be performed on a computing device, wherein the article of manufacture has a non-transitory memory configured to retain the instructions, the instructions comprising, at least in part:
obtaining at least one sample of the geological formation;
subjecting the at least one sample to a first nuclear magnetic resonance evaluation, wherein cutoff values are obtained when the at least one sample is saturated;
desaturating the at least one sample;
performing a second nuclear magnetic resonance evaluation of the desaturated at least one sample;
comparing the first nuclear magnetic resonance evaluation to the second nuclear magnetic resonance evaluation;
generating at least one correlation between the first and second nuclear magnetic resonance evaluations; and
determining the water saturation value of the geological formation based on the at least one correlation.

20. The article of manufacture according to claim 19, wherein the article is of a form of a solid-state memory device, a compact disk, a computer hard drive, and a universal serial bus device.
